(19) United States
(12) Patent Application Publication
(10) Pub. No.: US 2024/0293884 A1
(43) Pub. Date: Sep. 5, 2024

(54) SOLDER REFLOW APPARATUS AND METHOD OF MANUFACTURING ELECTRONIC DEVICE

(71) Applicant: Samsung Electronics Co., Ltd., Suwon-si (KR)

(72) Inventors: Youngja Kim, Suwon-si (KR); Seungyeop Oh, Suwon-si (KR)

(21) Appl. No.: 18/397,354

(22) Filed: Dec. 27, 2023

(30) Foreign Application Priority Data
Mar. 3, 2023 (KR) 10-2023-0028416

(51) Int. Cl. B23K 1/015; B23K 1/00; B23K 1/20; H01L 21/56; H01L 23/00

(52) U.S. Cl. CPC B23K 1/015; B23K 1/0016; B23K 1/20; H01L 21/56; H01L 24/81; B23K 2101/40; H01L 2224/81815

(57) ABSTRACT

In a method of manufacturing an electronic device, a substrate having a plurality of bonding pads formed on a first surface of the substrate is provided. Solder balls are attached on the bonding pads respectively. At least one radiant heating cover is disposed on the first surface of the substrate to cover the solder balls. The substrate on which the at least one radiant heating cover is disposed is loaded into a vapor generating chamber that accommodates a heat transfer fluid therein. The heat transfer fluid is heated to form the heat transfer fluid in a vapor phase within the chamber. The solder balls are soldered by transferring heat generated when the heat transfer fluid in the vapor phase is brought to contact a surface of the radiant heating cover and condenses toward the solder balls as radiant heat emitted from the radiant heating cover.

### PRIORITY STATEMENT

This application claims priority under 35 U.S.C. § 119 to Korean Patent Application No. 10-2023-0028416, filed on Mar. 3, 2023 in the Korean Intellectual Property Office (KIPO), the contents of which are herein incorporated by reference in their entirety.

### BACKGROUND

### 1. Field

Example embodiments relate to a solder reflow apparatus and a method of manufacturing an electronic device using the same. More particularly, example embodiments relate to a solder reflow apparatus using a vapor phase soldering method and a method of manufacturing a semiconductor package using the same.

### 2. Description of the Related Art

A convection reflow method, a laser assisted bonding method, a vapor phase soldering method, or the like may be used to solder a solder paste in the field of surface mount technology (SMT). In case of the vapor phase soldering method among them, when reflowing solder balls on bonding pads of a substrate such as a printed circuit board (PCB), as diameters and volumes of the solder balls decrease, the airflow around the solder balls or a heat transfer fluid condensed from a gaseous state to a liquid state on the substrate surface may move the solder balls, resulting in solder ball mounting defects.

### SUMMARY

Example embodiments provide a method of manufacturing an electronic device capable of preventing solder ball mounting defects.

Example embodiments provide a solder reflow apparatus for performing the above manufacturing method.

According to example embodiments, in a method of manufacturing an electronic device, a substrate having a plurality of bonding pads formed on a first surface of the substrate is provided. Solder balls are attached on the bonding pads respectively. At least one radiant heating cover is disposed on the first surface of the substrate to cover the solder balls. The substrate on which the at least one radiant heating cover is disposed is loaded into a vapor generating chamber that accommodates a heat transfer fluid therein. The heat transfer fluid is heated to form the heat transfer fluid in a vapor phase within the chamber. The solder balls are soldered by transferring heat generated when the heat transfer fluid in the vapor phase is brought to contact a surface of the radiant heating cover and condense toward the solder balls as radiant heat emitted from the radiant heating cover.

According to example embodiments, in a method of manufacturing an electronic device, a substrate having a plurality of bonding pads formed on a first surface of the substrate is provided. Solder balls are attached on the bonding pads respectively. At least one radiant heating cover is disposed on the first surface of the substrate to cover the solder balls. The substrate on which the at least one radiant heating cover is disposed is loaded into a vapor generating chamber that accommodates a first heat transfer fluid therein. The first heat transfer fluid is heated to form a second heat transfer fluid in a vapor phase within the chamber. The second heat transfer fluid is supplied in the vapor phase to a surface of the radiant heating cover while the second heat transfer fluid in the vapor phase is blocked from moving to the solder balls under the radiant heating cover. The solder balls are soldered by transferring heat generated when the second heat transfer fluid is brought to contact a surface of the radiant heating cover and condenses toward the solder balls as radiant heat emitted from the radiant heating cover.

According to example embodiments, in a method of manufacturing an electronic device, a substrate having a plurality of bonding pads formed on a first surface of the substrate is provided. A solder paste is coated on the bonding pads. Solder members are attached on the bonding pads respectively. At least one radiant heating cover is disposed on the first surface of the substrate to cover the solder members. The substrate on which the at least one radiant heating cover is disposed is loaded into a vapor generating chamber that accommodates a first heat transfer fluid therein. The first heat transfer fluid is heated to form a second heat transfer fluid in a vapor phase within the chamber. The second heat transfer fluid is supplied in the vapor phase to a surface of the radiant heating cover while the second heat transfer fluid in the vapor phase is blocked from moving to the solder members under the radiant heating cover. The solder members are soldered by transferring heat generated when the second heat transfer fluid is brought to contact a surface of the radiant heating cover and condenses toward the solder members as radiant heat emitted from the radiant heating cover.

According to example embodiments, solder balls may be attached to bonding pads on a first surface of a substrate, at least one radiant heating cover may be disposed on the first surface of the substrate to cover the solder balls, and the solder balls may be reflowed by a vapor phase reflow method.

The substrate on which the radiant heating cover is disposed may be loaded into a vapor generating chamber of a solder reflow apparatus, and a heat transfer fluid in a vapor state may be brought into contact with an outer surface of the radiant heating cover to heat the radiant heating cover. The radiant heating cover may radiate internal heat toward the solder balls in the form of radiant heat. The solder balls may be bonded respectively to the bonding pads by the radiant heat from the radiant heating cover. In this case, the radiant heating cover may block the heat transfer fluid in the vapor state from moving onto the solder balls and the surface of the substrate inside the radiant heating cover.

Accordingly, while performing soldering by the radiant heat from the radiant heating cover, it may be prevented that the heat transfer fluid in the vapor state is brought to contact with the surface of the substrate and condenses and the heat transfer fluid in the liquid state moves and is brought to contact the solder ball. Thus, when the solder balls are reflowed by the vapor phase soldering method, solder ball mounting defects due to misalignment of the solder balls may be prevented.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 is a cross-sectional view illustrating a solder reflow apparatus according to some example embodiments.

FIG. 2 is a side view illustrating the solder reflow apparatus of FIG. 1.

FIG. 3 is a perspective view illustrating a substrate stage of the solder reflow apparatus of FIG. 1.

FIG. 4 is a perspective view illustrating an article supported on the substrate stage of FIG. 3.

FIG. 5 is a cross-sectional view illustrating solder balls on a substrate supported on the substrate stage of FIG. 1 and reflowed by a vapor phase reflow method.

FIG. 6 is a cross-sectional view illustrating a portion of a radiant heating cover disposed on the substrate of FIG. 5 to cover the solder balls.

FIG. 7 is a cross-sectional view illustrating a portion of a radiant heating cover disposed on the substrate of FIG. 5 to cover solder balls according to another example embodiment.

FIG. 8 is a flowchart illustrating a method of manufacturing an electronic device according to some example embodiments.

FIGS. 9 to 17 are views illustrating a method of manufacturing an electronic device according to some example embodiments.

### DETAILED DESCRIPTION OF EXAMPLE EMBODIMENTS

Hereinafter, example embodiments will be explained in detail with reference to the accompanying drawings.

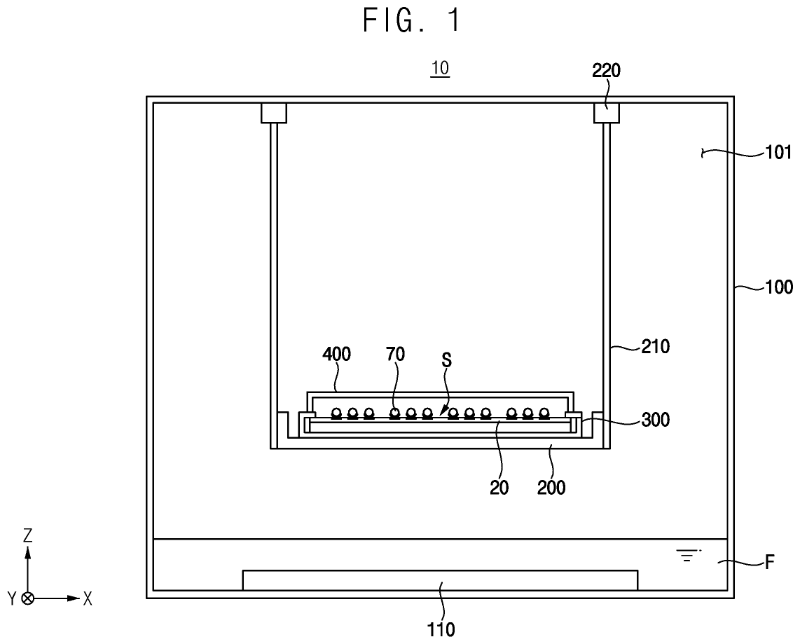

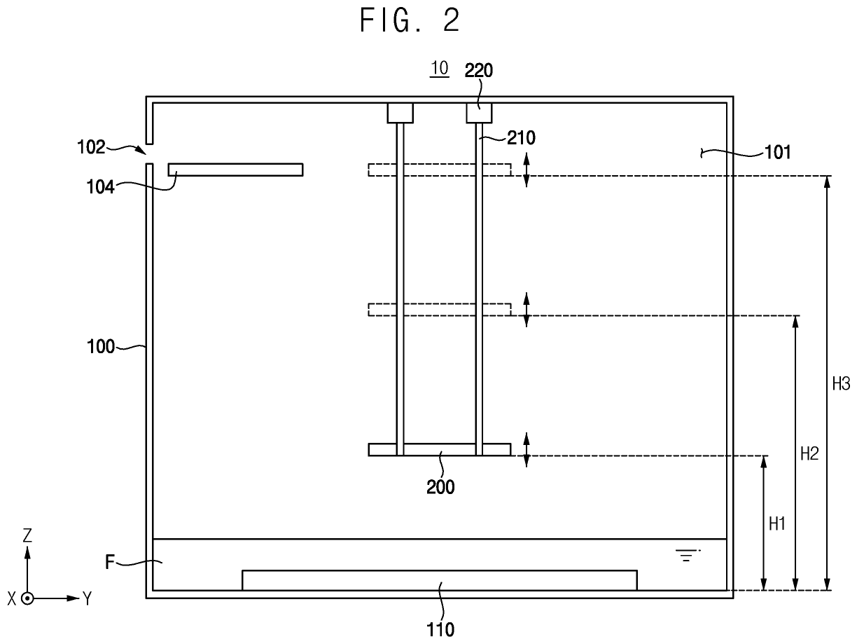

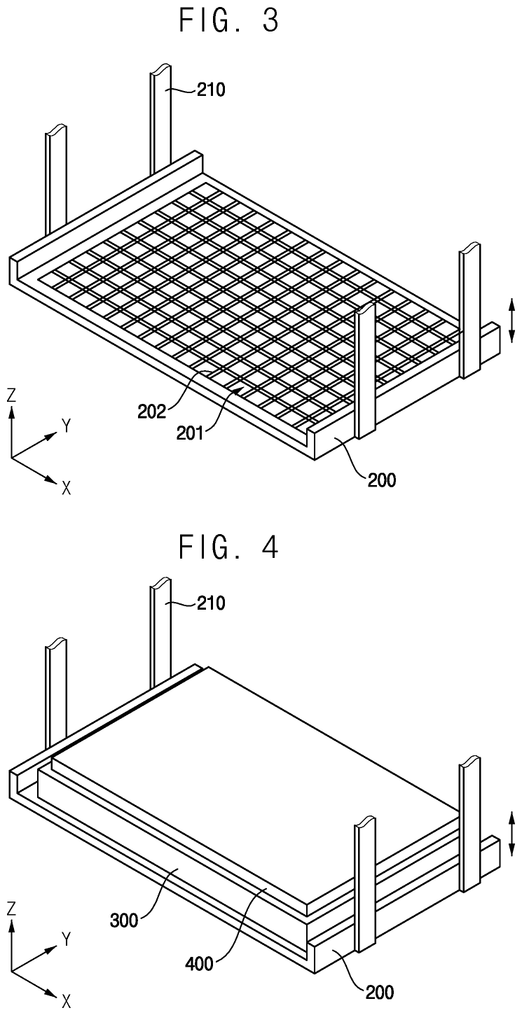

FIG. 1 is a cross-sectional view illustrating a solder reflow apparatus according to some example embodiments. FIG. 2 is a side view illustrating the solder reflow apparatus of FIG. 1. FIG. 3 is a perspective view illustrating a substrate stage of the solder reflow apparatus of FIG. 1. FIG. 4 is a perspective view illustrating an article supported on the substrate stage of FIG. 3.

Referring to FIGS. 1 to 4, a solder reflow apparatus 10 may include a vapor generating chamber 100, a heater 110 and a substrate stage 200. In addition, the solder reflow apparatus 10 may further include a lifting driver configured to raise and lower the substrate stage 200, a temperature sensing portion configured to monitor temperature in the vapor generating chamber 100, etc.

In example embodiments, the solder reflow apparatus 10 may be a vapor phase soldering apparatus configured to solder a solder paste or solder balls by saturated vapor heated in the vapor generating chamber 100.

The vapor generating chamber 100 may include a lower reservoir having an oven shape to accommodate a heat transfer fluid F and to provide a space 101 filled with vapor that is generated directly above the fluid when the fluid F is boiling. The vapor generating chamber 100 may extend in a vertical direction (Z direction) by a predetermined height. In the vapor generating chamber 100, the heat transfer fluid may boil and the vapor may rise to the top, may condense back to the liquid state at the top, and may flow back to the reservoir at the bottom.

Spatially relative terms, such as “vertical,” “horizontal,” “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The pressure inside the vapor generating chamber 100 may be maintained at atmospheric pressure. Alternatively or additionally, the vapor generating chamber 100 may be connected to an exhaust device such as a vacuum pump to adjust the pressure inside the vapor generating chamber 100. The pressure inside the vapor generating chamber may be maintained at a predetermined pressure in order to change the boiling point of the heat transfer fluid or soldering environments.

The heat transfer fluid F may be a chemical material that is selected to provide the vapor necessary for vapor phase soldering. The heat transfer fluid may be selected in consideration of boiling point, environmental influences, and corrosiveness of the generated vapor. The heat transfer fluid may include or be formed of an inert organic liquid. For example, the heat transfer fluid may include or may be a perfluoropolyether (PFPEs)-based Galden solution. The boiling point of the Galden solution may be 230° C.

The heater 110 may heat the heat transfer fluid F accommodated in the vapor generating chamber 100 to generate saturated vapor. The heater 110 may include an electrical resistor that is immersed in the heat transfer fluid F (e.g., when the heat transfer fluid F is accommodated in the vapor generating chamber 100) on the bottom of the vapor generating chamber 100. Alternatively or additionally, the heater 110 may include a resistor in the form of a coil surrounding the reservoir tank.

In addition, a heater (not illustrated) as a portion of a temperature control mechanism may be installed on a sidewall of the vapor generating chamber 100 to control the temperature of the vapor generating chamber 100 during a reflow process.

As illustrated in FIGS. 3 and 4, the substrate stage 200 may support an article S on which a solder process is performed in the vapor generating chamber 100. The substrate stage 200 may include a mesh type support structure for supporting the article S. The mesh type support structure may include support wires 202 that define a plurality of openings 201 through which the vapor moves. For example, the article S may include or may be a substrate 20 to which solder balls 70 are attached to one surface. The substrate 20 may be a printed circuit board (PCB) strip in which a plurality of PCBs (e.g., PCB layers) are integrally provided. The substrate 20 may not be limited to the PCB strip, and may be an individual PCB of a package unit or a wafer or die separated into individual units through a sawing process. The openings may have circular or polygonal shapes (e.g., rectangles). The sizes and shapes of the openings, thicknesses of support wires, etc. may be determined in consideration of the temperature profile in the vapor generating chamber.

The substrate stage 200 may be installed to be movable upward and downward within the vapor generating chamber 100. The lifting driver for moving the substrate stage 200 upward and downward may include various types of actuators such as a transfer rail, a transfer screw, a transfer belt, etc. Both end portions (e.g., opposite sides) of the substrate stage 200 may be supported by transfer rods 210 respectively, and the substrate stage 200 may be moved up and down by the lifting driver.

As illustrated in FIG. 2, the article S for soldering may be transferred into the vapor generating chamber 100 through a gate 102 of the vapor generating chamber 100, and the article S may be loaded on the substrate stage 200 by a transfer mechanism 104 such as a guide rail or a transport pusher (pusher transfer device).

After the article S is loaded, the Galden solution F may be heated by the heater 110 and start to boil. The saturated vapor from the Galden solution may be distributed within the space 101 of the vapor generating chamber 100. At this time, the density of the saturated vapor may vary depending on the height, and thus a temperature gradient may be formed.

For example, the temperature T1 of the vapor generating chamber at a third height H3 may be about 100° C., the temperature T2 of the vapor generating chamber at a second height H2 may be about 170° C., and the temperature T3 of the vapor generating chamber at a first height H1 may be about 230° C. The solder ball 70 may include or be formed of Sn—Ag—Cu (SAC) solder, Sn—Ag solder, etc. Since the boiling point of the SAC solder is 217° C., the temperature T3 at the first height H1, which is a reflow section, may be maintained at about 230° C.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

Hereinafter, a method of performing a vapor phase reflow process using the solder reflow apparatus of FIG. 1 will be described.

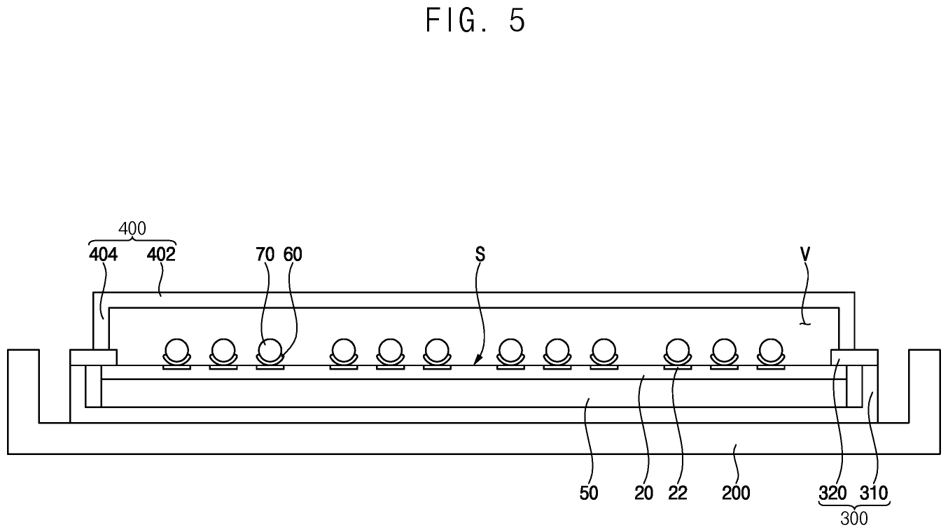

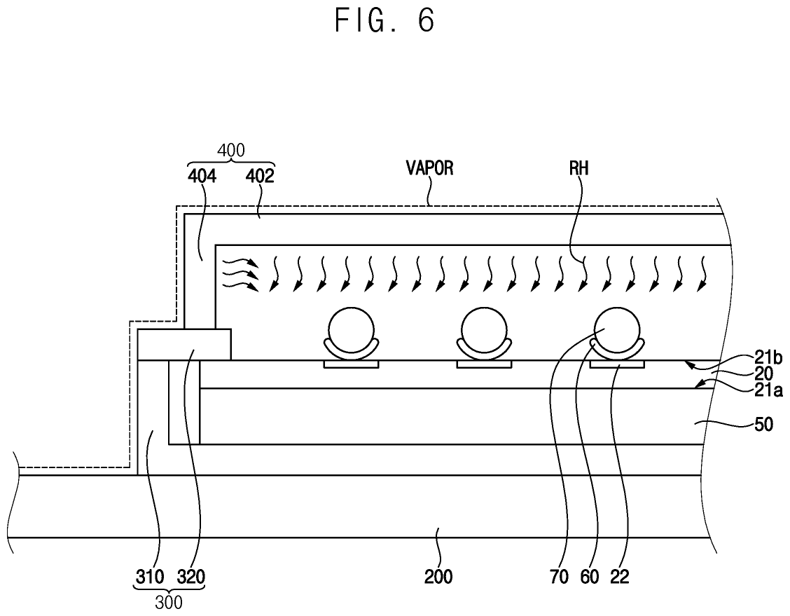

FIG. 5 is a cross-sectional view illustrating solder balls on a substrate supported on the substrate stage of FIG. 1 and reflowed by a vapor phase reflow method. FIG. 6 is a cross-sectional view illustrating a portion of a radiant heating cover disposed on/above the substrate of FIG. 5 to cover the solder balls.

Referring to FIGS. 5 and 6, first, an article S for soldering may be loaded into the vapor generating chamber 100, and the heat transfer fluid F in the vapor generating chamber 100 may be heated.

In example embodiments, after a semiconductor chip is mounted on a first surface 21a of the substrate 20 and a molding member 50 is formed to mold the semiconductor chip, a solder paste 60 and solder balls 70 may be attached onto bonding pads 22 as ball lands provided on a second surface 21b opposite to the first surface 21a of the substrate 20. The substrate 20 to which the solder balls 70 are attached may be transferred into the vapor generating chamber 100 through the gate 102 of the vapor generating chamber 100, and then, the article S (e.g., the substrate 20 with the solder balls 70 attached on it) may be loaded on the substrate stage 200 by the transfer mechanism 104 such as a guide rail or a transfer pusher (pusher transfer device).

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As illustrated in FIGS. 5 and 6, a radiant heating cover 400 may be disposed on/above the second surface 21b of the substrate 20 supported on the substrate stage 200, to cover (e.g., vertically overlap) the solder balls 70 attached to the bonding pads 22. For example, the substrate 20 to which the solder balls 70 are attached may be disposed fixedly on a fixing jig 300, and the fixing jig 300 on which the substrate 20 is disposed fixedly may be seated on the substrate stage 200 in the vapor generating chamber 100.

The fixing jig 300 may press and fix the substrate 20 of the article S. In a state in which the substrate 20 is pressurized and fixed, the fixing jig 300 may be supported on the seating surface of the substrate stage 200. The fixing jig 300 may include a lower jig 310 and an upper jig 320 disposed fixedly on the lower jig 310. The lower jig 310 may include a lower base plate on which the substrate 20 is seated. The upper jig 320 may be disposed fixedly on the lower jig 310 to press the substrate 20. The upper jig 320 and the lower jig 310 may be coupled to each other by a fixing member such as a magnetic material. The upper jig 320 may include an edge portion that presses a peripheral region of the substrate 20 and forms a window that exposes the solder balls 70 on the substrate 20.

In example embodiments, the radiant heating cover 400 may include a covering portion 402 extending parallel to the second surface 21b of the substrate 20 above the solder balls 70 and a support portion 404 extending (e.g., upwards) from the fixing jig 300 to support the covering portion 402. The covering portion 402 and the support portion 404 may form an enclosed space V that surround the solder balls 74 and is isolated from the outside. For example, the covering portion 402 may have a rectangular plate shape, and the support portion 404 may include first to fourth support plates vertically (e.g., downwardly) extending from first to fourth side portions of the covering portion 402. The support portion 404 may extend upward from the edge portion of the upper jig 320. The support portion 404 may be detachably fastened to the upper jig 320 by a fastening member such as Velcro.

Alternatively, the radiant heating cover 400 may be supported on the second surface 21b of the substrate 20. For example, the support portion 404 of the radiant heating cover 400 may be detachably fastened to the peripheral region of the second surface 21b of the substrate 20.

The radiant heating cover 400 may include or be formed of a material having high radiation emissivity. For example, the radiant heating cover 400 may have an emissivity of at least 0.5. The radiant heating cover 400 may include or be formed of a metal such as stainless steel or ceramic, but is not limited thereto. The radiant heating cover 400 may block the heat transfer fluid in a vapor state in the vapor generating chamber 100 from moving to the solder balls 70. The radiant heating cover 400 may absorb heat generated when the heat transfer fluid in the vapor state is brought to contact an outer surface of the radiant heating cover 400 and condenses. Then, the radiant heating cover 400 may radiate the internal heat toward the solder balls 70 inside the radiant heating cover 400 in the form of radiant heat. Due to the radiant heat, the solder ball 70 may be reflowed to be bonded to the bonding pad 22.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

For example, after the fixing jig 300 in which the substrate 20 having the solder balls 70 attached thereon is fixedly supported and on which the radiant heating cover 400 is disposed is loaded into the vapor generating chamber 100, the Galden solution F may be heated by the heater 110 and start to boil. The saturated vapor from the Galden solution may be distributed within the space 101 of the vapor generating chamber 100. At this time, the vapor may have a density gradient according to the height, and thus, a temperature gradient along the vertical direction within the vapor generating chamber 100 may be formed.

After the substrate 20 is preheated at the third height H3, the substrate may be moved to the second height H2 and activated (soaked). The substrate 20 may be preheated to prevent various soldering defects and to provide a more solid and conductive joint. There may be a secondary vapor phase which is produced at a cooler temperature than the main vapor layer at the third and second heights H3 and H2. No soldering takes place in this zone, only a temperature rises.

The substrate 20 may be moved to the first height H1 so that the solder balls 70 may be reflowed. When the substrate 20 is immersed in the vapor at the first height H1, the vapor may serves as a heat transfer medium. Since the temperature of the vapor and the temperature of the radiant heating cover 400 above the second surface 21b of the substrate 20 at the first height H1 are different from each other, vapor may be condensed on a surface of the radiant heating cover 400 to form a layer. The vapor condensing on the surface may transfer latent heat to the surface of the radiant heating cover 400 during condensation to increase the temperature of the radiant heating cover 400. The radiant heating cover 400 may radiate internal heat toward the solder balls 70 inside (e.g., below) the radiant heating cover 400 in the form of radiant heat (RH). Heat (Q) transferred from the radiant heating cover 400 to the solder balls 70 may be expressed by Equation (1) below.

$$Q = ϵ σ A ( T {1}^{4} - T {2}^{4} ) \qquad Equation ( 1 )$$

Here, ε is emissivity, σ is Boltzmann constant, A is inner area of the radiant heating cover, T1 is temperature of the radiant heating cover, and T2 is temperature of the solder ball.

The solder balls 70 may be bonded respectively to the bonding pads 22 by the radiant heat RH from the radiant heating cover 400. In this case, the radiant heating cover 400 may block the heat transfer fluid in the vapor state from moving onto the solder balls 70 and the second surface 21b of the substrate 20 under the radiant heating cover 400.

Accordingly, while performing soldering by the radiant heat (RH) from the radiant heating cover 400, it may be prevented that the heat transfer fluid in the vapor state is brought to contact with the second surface 21b of the substrate 20 and condenses on it, and the heat transfer fluid in the liquid state is brought to contact and moves the solder ball 70. Thus, when the solder balls are reflowed by the vapor phase soldering method, solder ball mounting defects due to misalignment of the solder balls may be prevented.

Then, after the solder balls 70 are soldered, the substrate 20 may move to the top of the chamber and then may be cooled. Accordingly, the solder joints may be cooled down and solidified.

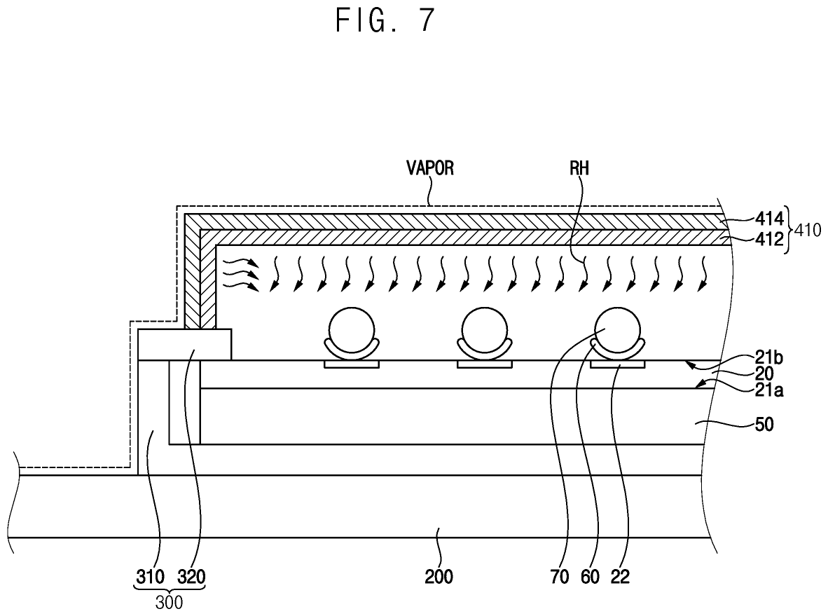

FIG. 7 is a cross-sectional view illustrating a portion of a radiant heating cover disposed on the substrate of FIG. 5 to cover solder balls according to another example embodiment.

Referring to FIG. 7, a radiant heating cover 410 may include or be formed of a multilayer structure in which at least two layers are stacked. The radiant heating cover 410 may include an inner cover 412 to cover solder balls 70 on a second surface 21b of a substrate 20 and an outer cover 414 provided on the inner cover 412.

In example embodiments, the inner cover 412 may have a first thermal conductivity and a first emissivity, and the outer cover 414 may have a second thermal conductivity greater than the first thermal conductivity and a second emissivity smaller than the first emissivity. The outer cover 414 having relatively high thermal conductivity may well absorb heat generated when the heat transfer fluid in a vapor state is brought to contact an outer surface of the outer cover, and the inner cover 412 having a relatively high emissivity may efficiently radiate the heat transferred from the outer cover 414 in the form of radiant heat. For example, the inner cover 412 may include or be formed of ceramic and the outer cover 414 may include or be formed of stainless steel.

Alternatively, the radiant heating cover 410 may include or may be a dome-shaped cover covering the solder balls 70 on the second surface 21b of the substrate 20, a heat absorbing layer formed on an outer surface of the cover, and a heat dissipation layer formed on an inner surface of the cover.

In example embodiments, a plurality of radiant heating covers may cover the solder balls 70 on the second surface 21b of the substrate 20. For example, three radiant heating covers may be disposed on the second surface 21b of the substrate 20. The solder balls 70 may be grouped into first to third groups, a first radiation heating cover may cover the first group of the solder balls 70, the second radiation heating cover may cover the second group of the solder balls 70, and the third radiation heating cover may cover the third group of solder balls 70.

In example embodiments, a radiant heating cover may cover only some of the solder balls 70, and the remaining solder balls may be exposed by the radiant heating cover. For example, some solder balls may not be covered by the radiant heating cover in certain embodiments.

Hereinafter, a method of manufacturing an electronic device using the solder reflow apparatus of FIG. 1 will be described. A case in which the electronic device is a semiconductor package will be described. However, it will be understood that the manufacturing method of the electronic device according to example embodiments is not limited thereto.

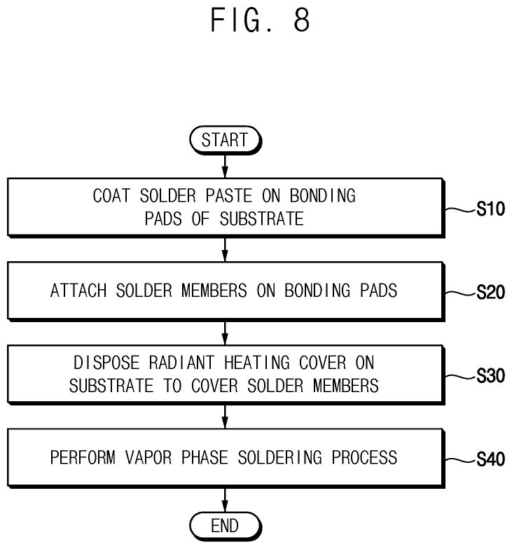

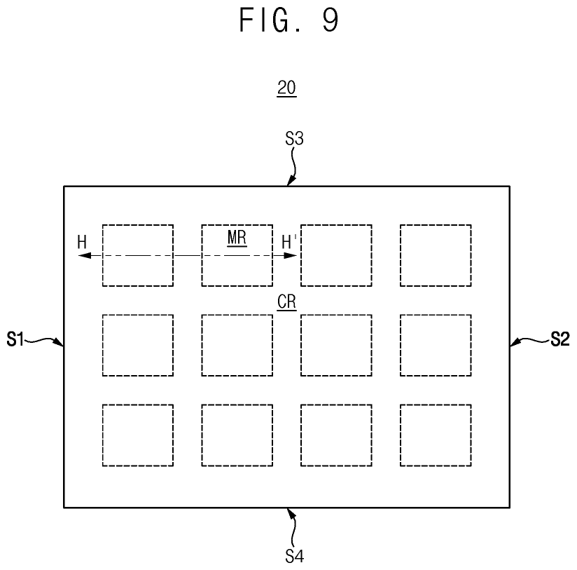

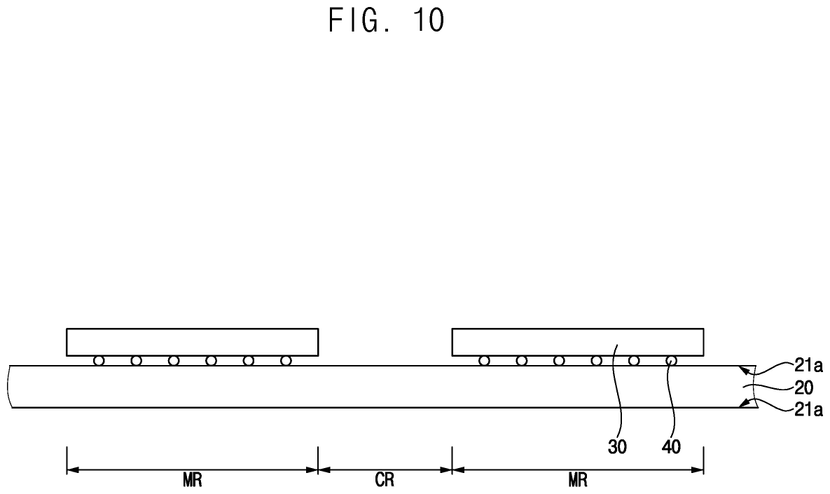

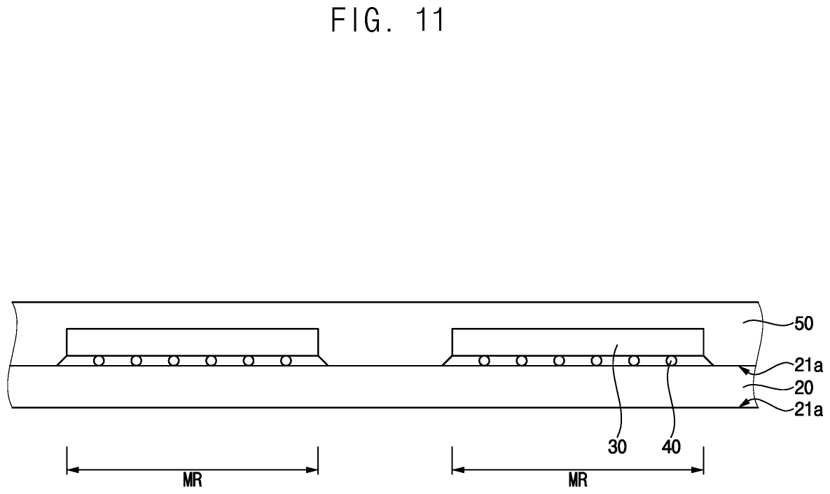

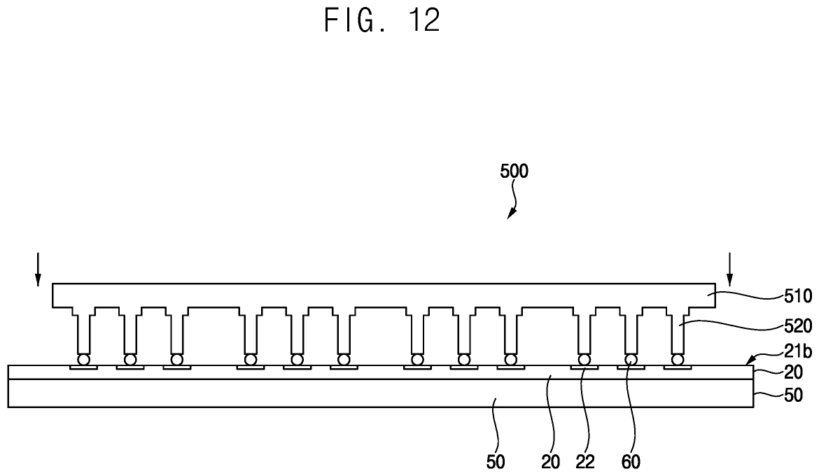

FIG. 8 is a flowchart illustrating a method of manufacturing an electronic device according to some example embodiments. FIGS. 9 to 17 are views illustrating a method of manufacturing an electronic device according to some example embodiments. FIG. 9 is a plan view illustrating a strip substrate on which semiconductor chips are mounted. FIGS. 10 and 11 are cross-sectional views taken along the line H-H′ in FIG. 9.

Referring to FIGS. 8 to 11, first, a substrate 20 having a first surface 21a and a second surfaces 21b opposite to each other and having bonding pads 22 as ball lands formed thereon may be provided.

As illustrated in FIG. 9, the substrate 20 may be a multilayer circuit board as a package substrate. The substrate 20 may be a strip substrate for manufacturing a semiconductor strip such as a printed circuit board (PCB). Alternatively, the substrate 20 may be a semiconductor chip or an interposer.

The substrate 20 may have first and second side portions (e.g., side surfaces) S1 and S2 extending, e.g., lengthwise, in a direction parallel to a second direction (Y direction) parallel to the first surface 21a and opposite each other, and third and fourth side portions (e.g., side surfaces) S3 and S4 extending, e.g., lengthwise, in a direction parallel to a first direction (X direction) perpendicular to the second direction and opposite each other. When viewed from a plan view, the substrate 20 may have a quadrangular shape (e.g., a rectangle). The substrate 20 may have a predetermined area (e.g., 77.5 mm×240 mm).

The substrate 20 may include one or more mounting regions MR on which one or more electronic components are mounted and a cutting region CR surrounding the mounting regions MR. A plurality of semiconductor chips as the electronic components may be disposed on the mounting regions MR of the substrate 20 respectively. For example, each of the semiconductor chips may include or may be a logic semiconductor device or a memory device. The logic semiconductor device may be an ASIC as a host such as a CPU, GPU, or SoC. The memory device may include or may be a high bandwidth memory (HBM) device. Alternatively, each of the electronic components may include or may be a passive element such as a capacitor.

Referring to FIGS. 9 and 10, tens to hundreds of semiconductor chips 30 may be arranged in a matrix form on the substrate 20. The semiconductor chips 30 may be mounted on the first surface 21a of the substrate 20. For example, the semiconductor chips 30 may be mounted on the first surface 21a of the substrate 20 by a flip chip bonding method. The semiconductor chips 30 may be mounted on the first surface 21a of the substrate 20 via bumps 40. Alternatively, the semiconductor chips 30 may be attached to the first surface 21a of the substrate 20 by an adhesive film and electrically connected to the substrate 20 by bonding wires.

As illustrated in FIG. 11, a molding member 50 may be formed on the first surface 21a of the substrate 20 to cover the semiconductor chips 30. For example, the molding member 50 may be formed on the substrate 20 by a transfer molding apparatus. For example, the molding member 50 may be a molding layer, e.g., formed of a resin. For example, the substrate 20 may be disposed in a molding space of a mold of the molding apparatus, and a sealing/casting material may be injected to flow at high temperature and high pressure in a state where a lower mold and an upper mold are clamped, so that the liquid sealing material flows inside the molding space and is solidified to form the molding member 50 covering the semiconductor chips 30. For example, the sealing material may include or may be an epoxy mold compound (EMC).

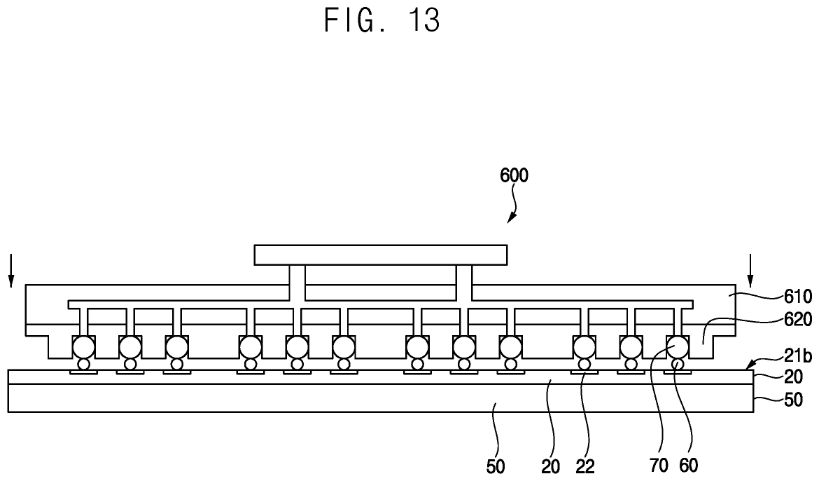

As illustrated in FIG. 12, a solder paste 60 may be coated on each of a plurality of bonding pads 22 on the second surface 21b of the substrate 20 (S10). A pitch between the bonding pads 22 of the substrate 20 may be within a range of several tens of microns.

For example, the substrate 20 may be transferred onto a stage of a flux coating apparatus 500, a body 510 of the flux coating apparatus 500 may be lowered onto the substrate 20 and dotting pins 520 of the flux coating apparatus 500 may dot the solder paste 60 on the bonding pads 22 of the substrate 20. The flux coating apparatus 500 may include the body 510 and a plurality of the dotting pins 520 extending from the body 510 in one direction (e.g., downwardly). The dotting pins 520 may move to a flux reservoir, apply the solder paste 60 to ends of the dotting pins 520, and dot the solder paste 60 on the bonding pads 22 of the substrate 20. For example, the solder paste 60 may be transferred from the dotting pins 520 onto the bonding pads 22. The solder paste 60 may include or be formed of solder powder and flux. The flux may include resin, solvent, activator, antioxidant, etc.

Alternatively, the solder paste 60 may be printed onto the bonding pads 22 of the substrate 20. For example, the solder paste 60 may be printed by a stencil printer. A stencil may be a metal foil having a plurality of openings corresponding to an array of solder balls to be subsequently placed. During printing, the solder paste 60 may be printed to fill openings of the stencil.

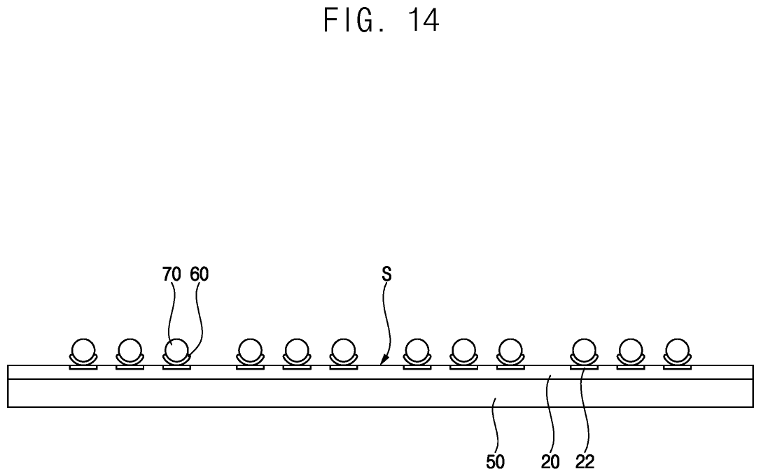

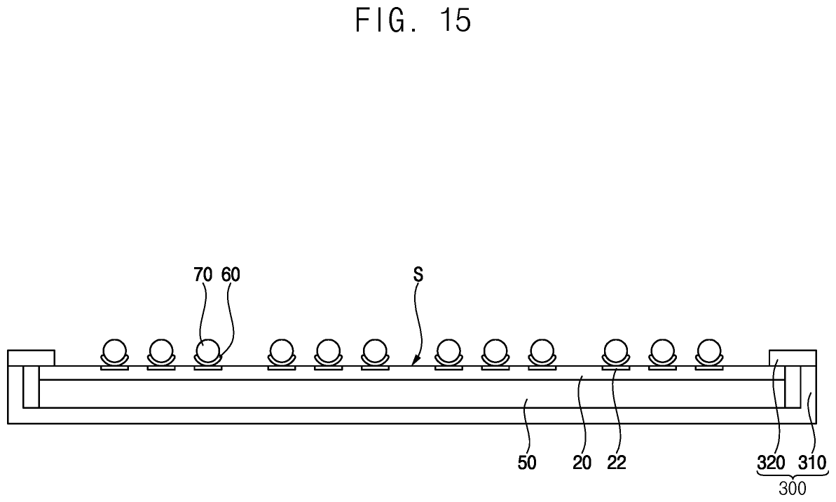

Referring to FIGS. 13 and 14, solder balls 70 as solder members may be attached to the bonding pads 22 to which the solder paste 60 is coated (S20).

For example, the substrate 20 may be transferred onto a stage of the solder member attachment apparatus 600, and the solder balls 70 adsorbed to suction holes of the solder member attachment device 600 by a vacuum adsorption method may be attached to the bonding pads 22 of the substrate 20 respectively. The solder member attachment apparatus 600 may include a body 610 and a solder ball holding portion 620. The body 610 may include an internal space which is in communication with an external vacuum generating device, and the solder ball holding portion 620 may include a plurality of suction holes which in communication with the internal space and selectively adsorbs the solder balls respectively. A vacuum may be applied to the suction holes to adsorb the solder balls 70, and the solder balls may be attached to the bonding pads 22 of the substrate 20 by removing the vacuum from the suction holes.

Accordingly, as illustrated in FIG. 14, an article S in which the solder paste 60 and the solder ball 70 are sequentially disposed on the bonding pad 22 of the substrate 20 may be provided.

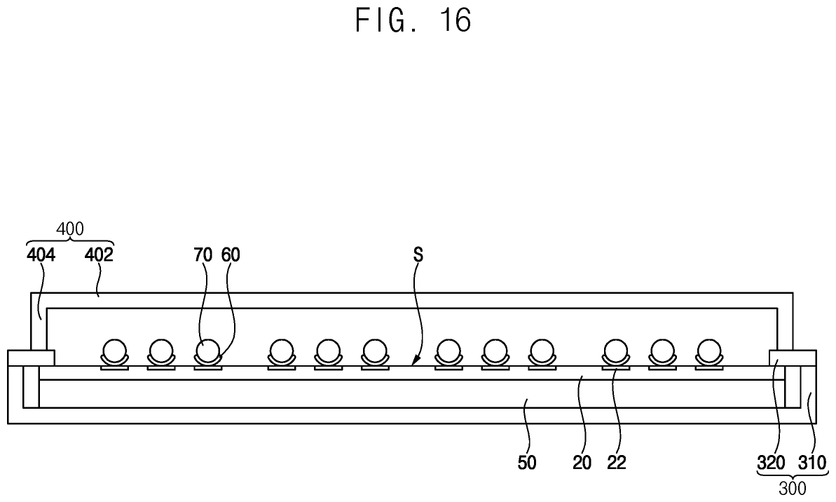

Referring to FIGS. 15 to 17, a radiant heating cover 400 may be disposed on the substrate 20 to cover the solder balls 70 (S30), and soldering of the solder ball 70 may be performed using a vapor phase reflow method (S40).

In example embodiments, first, the substrate 20 may be disposed fixedly on a fixing jig 300 and the radiant heating cover 400 may be disposed on the substrate 20.

As illustrated in FIG. 15, the substrate 20 to which the solder balls 70 are attached may be disposed on a lower jig 310 of the fixing jig 300, and an upper jig 320 may be disposed fixedly on the lower jig 310 to press the substrate 20. The upper jig 320 may include an edge portion that presses a peripheral region of the substrate 20 and forms a window that exposes the solder balls 70 in a central/inner region on the substrate 20.

As illustrated in FIG. 16, the radiant heating cover 400 may be disposed above the substrate 20 to cover the solder balls 70. The radiant heating cover 400 may include a covering portion 402 extending parallel to the second surface 21b of the substrate 20 above the solder balls 70 and a support portion 404 extending (e.g., upward) from the fixing jig 300 to support the covering portion 402. The covering portion 402 and the support portion 404 may form an enclosed space V that surround the solder balls 74 and is isolated from the outside. The support portion 404 may be detachably fastened to the upper jig 320 by a fastening member such as Velcro. For example, the support portion 404 of the radiant heating cover 400 may contact the upper jig 320 of the fixing jig 300 when the radiant heating cover 400 is disposed above the substrate 20 and covers the solder balls 70, e.g., while the soldering of the solder ball 70 is performed.

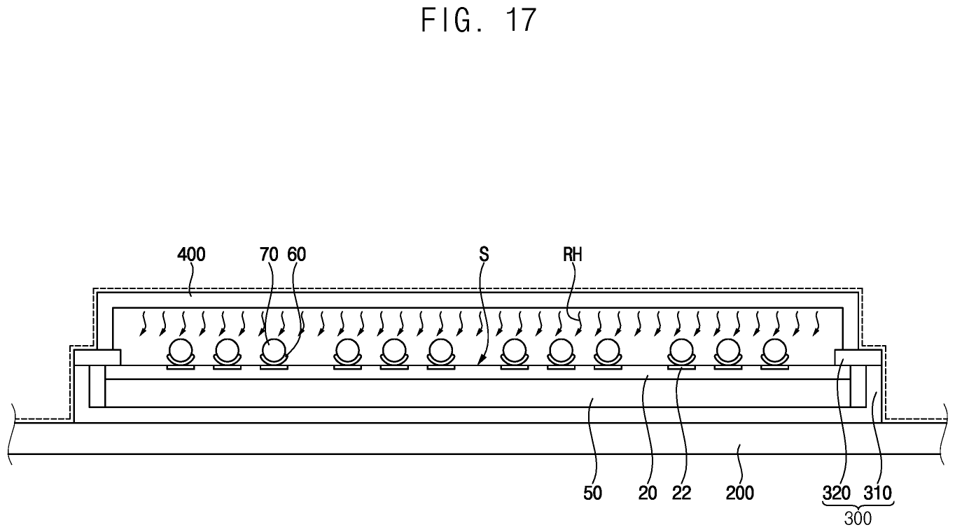

Referring to FIG. 17, the substrate 20 on which the solder balls 70 are attached may be loaded into the vapor generating chamber 100 of the solder reflow apparatus 10 of FIG. 1, and while the substrate 20 (e.g., encapsulated by the fixing jig 300 and the radiant heating cover 400) is sequentially moved in the vertical direction within the vapor generating chamber 100, the heat transfer fluid in a vapor state may be brought into contact with an outer surface of the radiant heating cover 400, so that the solder paste is soldered by radiant heat from the radiant heating cover 400.

When the radiant heating cover 400 is immersed in the vapor at the first height H1, the vapor may serves as a heat transfer medium. The vapor condensing on the surface may transfer latent heat to the surface of the radiant heating cover 400 during condensation to increase the temperature of the radiant heating cover 400. The radiant heating cover 400 may radiate internal heat toward the solder balls 70 inside the radiant heating cover 400 in the form of radiant heat (RH). The solder balls 70 may be bonded respectively to the bonding pads 22 by the radiant heat RH from the radiant heating cover 400. In this case, the radiant heating cover 400 may block the heat transfer fluid in the vapor state from moving onto the solder balls 70 and the second surface 21b of the substrate 20 inside the radiant heating cover 400.

Accordingly, since soldering is performed by the radiant heat (RH) from the radiant heating cover 400, it may be prevented that the heat transfer fluid in the vapor state is brought to contact with the second surface 21b of the substrate 20 and condenses on the second surface 21b of the substrate 20 and the heat transfer fluid in the liquid state is brought to contact and move the solder ball 70. Thus, when the solder balls are reflowed by the vapor phase soldering method, solder ball mounting defects due to misalignment of the solder balls may be prevented.

Then, after the solder balls 70 are soldered, the substrate 20 may move to the top of the chamber and then may be cooled. Accordingly, the solder joints may be cooled down and solidified.

After the substrate 20 on which the solder balls 70 have been soldered is unloaded from the solder reflow apparatus 10 of FIG. 1, the radiant heating cover 400 may be removed from the second surface 21b of the substrate 20.

Then, the substrate 20 and the molding member 50 may be sawed by a sawing process to complete individual semiconductor packages.

Through the above processes, a semiconductor package including a logic device or a memory device and a semiconductor module including the same may be manufactured. The semiconductor packages may include or may be logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A method of manufacturing an electronic device, the method comprising:
providing a substrate having a plurality of bonding pads formed on a first surface of the substrate;
attaching solder balls on the plurality of bonding pads respectively;
disposing at least one radiant heating cover on the first surface of the substrate to cover the solder balls;
loading the substrate on which the at least one radiant heating cover is disposed into a vapor generating chamber that accommodates a heat transfer fluid therein;
heating the heat transfer fluid to form the heat transfer fluid in a vapor phase within the chamber; and
soldering the solder balls by transferring heat generated when the heat transfer fluid in the vapor phase is brought to contact a surface of the radiant heating cover and condenses, toward the solder balls as radiant heat emitted from the radiant heating cover.

2. The method of claim 1, wherein the at least one radiant heating cover comprises metal or ceramic.

3. The method of claim 1, wherein the at least one radiant heating cover has emissivity of at least 0.5.

4. The method of claim 1, wherein the at least one radiant heating cover comprises:
an inner cover on the first surface of the substrate to cover the solder balls; and
an outer cover provided on the inner cover.

5. The method of claim 4, wherein the inner cover has a first thermal conductivity and a first emissivity, and the outer cover has a second thermal conductivity greater than the first thermal conductivity and a second emissivity smaller than the first emissivity.

6. The method of claim 1, wherein loading the substrate into the chamber comprises loading the substrate onto a substrate stage in the chamber.

7. The method of claim 1, further comprising:
coating a solder paste on the plurality of bonding pads before attaching the solder balls on the bonding pads respectively.

8. The method of claim 1, further comprising:
after attaching the solder balls on the plurality of bonding pads respectively, disposing fixedly the substrate on a fixing jig,
wherein loading the substrate into the chamber comprises placing the fixing jig on which the substrate is disposed fixedly on a substrate stage in the chamber.

9. The method of claim 1, wherein disposing the at least one radiant heating cover on the first surface of the substrate comprises disposing the at least one radiant heating cover on a fixing jig.

10. The method of claim 1, wherein the heat transfer fluid comprises a Galden solution.

11. A method of manufacturing an electronic device, the method comprising:
providing a substrate having a plurality of bonding pads formed on a first surface of the substrate;
attaching solder balls on the bonding pads respectively;
disposing at least one radiant heating cover on the first surface of the substrate to cover the solder balls;
loading the substrate on which the at least one radiant heating cover is disposed into a vapor generating chamber that accommodates a first heat transfer fluid therein;
heating the first heat transfer fluid to form a second heat transfer fluid in a vapor phase within the chamber;
supplying the second heat transfer fluid in the vapor phase to a surface of the radiant heating cover and blocking the second heat transfer fluid in the vapor phase from moving to the solder balls under the radiant heating cover; and
soldering the solder balls by transferring heat generated when the second heat transfer fluid is brought to contact the surface of the radiant heating cover and condenses, toward the solder balls as radiant heat emitted from the radiant heating cover.

12. The method of claim 11, wherein the at least one radiant heating cover comprises metal or ceramic.

13. The method of claim 11, wherein the at least one radiant heating cover has emissivity of at least 0.5.

14. The method of claim 11, wherein the at least one radiant heating cover comprises:
an inner cover on the first surface of the substrate to cover the solder balls; and
an outer cover provided on the inner cover.

15. The method of claim 14, wherein the inner cover has a first thermal conductivity and a first emissivity, and the outer cover has a second thermal conductivity greater than the first thermal conductivity and a second emissivity smaller than the first emissivity.

16. The method of claim 11, further comprising:
coating a solder paste on the bonding pads before attaching the solder balls on the bonding pads respectively.

17. The method of claim 11, further comprising:
after attaching the solder balls on the plurality of bonding pads respectively, disposing fixedly the substrate on a fixing jig,
wherein loading the substrate into the chamber comprises placing the fixing jig on which the substrate is disposed fixedly on a substrate stage in the chamber.

18. The method of claim 17, wherein disposing the at least one radiant heating cover on the first surface of the substrate comprises disposing the at least one radiant heating cover on the fixing jig.

19. The method of claim 11, wherein providing the substrate comprises:
mounting at least one semiconductor chip on a second surface of the substrate opposite to the first surface; and
forming a molding layer covering the at least one semiconductor chip on the second surface of the substrate.

20. A method of manufacturing an electronic device, the method comprising:
providing a substrate having a plurality of bonding pads formed on a first surface of the substrate;
coating a solder paste on the plurality of bonding pads;
attaching solder members on the bonding pads respectively;
disposing at least one radiant heating cover on the first surface of the substrate to cover the solder members;
loading the substrate on which the at least one radiant heating cover is disposed into a vapor generating chamber that accommodates a first heat transfer fluid therein;
heating the first heat transfer fluid to form a second heat transfer fluid in a vapor phase within the chamber;
supplying the second heat transfer fluid in the vapor phase to a surface of the radiant heating cover and blocking the second heat transfer fluid in the vapor phase from moving to the solder members under the radiant heating cover; and
soldering the solder members by transferring heat generated when the second heat transfer fluid is brought to contact the surface of the radiant heating cover and condenses, toward the solder members as radiant heat emitted from the radiant heating cover.
